(19) United States
(12) Patent Application Publication
(10) Pub. No.: US 2024/0266449 A1
(43) Pub. Date: Aug. 8, 2024

(54) REFLECTIVE OPTICAL SENSOR

(71) Applicant: Dexerials Corporation, Tochigi (JP)

(72) Inventors: Akihiro TATEKOUJI, Tochigi (JP); Etsuji OMURA, Tochigi (JP)

(73) Assignee: Dexerials Corporation, Tochigi (JP)

(21) Appl. No.: 18/638,618

(22) Filed: Apr. 17, 2024

Related U.S. Application Data
(63) Continuation of application No. PCT/JP2021/038923, filed on Oct. 21, 2021.

(51) Int. Cl. H01L 31/0232; H01L 31/16

(52) U.S. Cl. CPC H01L 31/02327; H01L 31/16

(57) ABSTRACT

A reflective optical sensor (1A) having a light emitting element (3) and a light receiving element (4) detects an object (OB) to be detected by reflected light reflected by the object (OB), and the sensor(1A) has an case (2) in which first and second concave mirrors (5, 6) are fitted, each of which has a reflective surface comprising a partial concave surface of a rotational ellipse surface rotated around a major axis, one focal point of the first concave mirror (5) and one focal point of the second concave mirror (6) are coincide to be a common focal point (F0), and the light emitting element (3) is fitted at the focal point (F1), the light receiving element is fitted at the focal point (F2).

### CROSS-REFERENCE TO RELATED APPLICATION

This application is a continuation of the International PCT application serial no. PCT/JP2021/038923, filed on Oct. 21, 2021. The entirety of the above-mentioned patent application is hereby incorporated by reference herein and made a part of this specification.

### TECHNICAL FIELD

The present disclosure relates to a reflective optical sensor that detects an object to be detected by irradiating light and detecting the light reflected by the object to be detected.

### BACKGROUND ART

Conventionally, reflective optical sensors have been widely used to detect objects to be detected by irradiating light and detecting the reflected light from nearby objects. Reflective optical sensors can detect objects without contact, and are commonly used in applications such as rotation angle detection and object edge detection, for example.

A reflective optical sensor, for example as in Patent Document #1, has a light emitting element, a light receiving element, and a light blocking wall arranged between them, so that the light irradiated by the light emitting element is reflected by an object to be detected, and this reflected light is received by the light receiving element. And it uses changes in the output of the light receiving element, depending on the presence or absence of the reflected light and the intensity of the reflected light, for detecting the object to be detected.

### PATENT DOCUMENTS

Patent Document #1: JP. Application Publication No. 2001-308372

In the reflective optical sensor of Patent Document #1, the light emitting element irradiates diffused light onto the nearby object to be detected. Therefore, most of the light emitted by the light emitting element is irradiated onto a nearby object to be detected, but even if the object to be detected has a high reflectance, the amount of the light reflected by the object to be detected and incident on the light receiving element is small. For example, when coupling efficiency is defined as the ratio of light incident on the light receiving element to the light emitted by the light emitting element, the coupling efficiency is about 3% according to the results of a ray tracing simulation in the reflective optical sensor of Patent Document #1, therefore, it is desired to improve the coupling efficiency.

An object of the present disclosure is to provide a reflective optical sensor that can improve coupling efficiency.

### SUMMARY OF THE DISCLOSURE

The present disclosure presents a reflective optical sensor comprising a light emitting element and a light receiving element, and detecting an object to be detected by reflected light emitted from the light emitting element and reflected by the object to be detected from the light emitting element with the light receiving element; wherein provided is a case in the form of an open box integrally formed with a first concave mirror and a second concave mirror, each of which has a reflective surface comprising a partial concave surface of a rotational ellipse surface rotated around a major axis of an ellipse, the first concave mirror and the second concave mirror are formed open toward an open side of the case so that one focal point of the first concave mirror is coincident with one focal point of the second concave mirror as a common focal point and a first focal point, which is the other focal point of the first concave mirror, does not overlap with a second focal point, which is the other focal point of the second concave mirror, the light emitting element emits light from the first focal point toward the first concave mirror, the first concave mirror reflects the light to the object to be detected which is positioned at or near the common focal point, and the second concave mirror reflects light reflected by the object to be detected, and the light receiving element is configured to detect light reflected by the second concave mirror at the second focal point.

According to the above configuration, the reflective optical sensor has the case in which first and second concave mirrors each having the partial concave surface of rotational ellipse surface as the reflective surface are integrally formed. The first and second concave mirrors are formed so that one focal point of each mirror is the common focal point and the other focal point of each mirror does not overlap. Then, the light emitting element at the first focal point of the first concave mirror, which is not the common focal point, emits light toward the first concave mirror, and light reflected by the first concave mirror is irradiated to the object to be detected located at or near the common focal point. Then, light reflected by the object to be detected is reflected by the second concave mirror and enters the light receiving element at the second focal point of the second concave mirror, which is not the common focal point. The light emitted from the first focal point is focused on the common focal point by the first concave mirror, so most of the light from the light emitting element is irradiated onto the object to be detected, and is reflected toward the second concave mirror. Since this reflected light was reflected at or near the common focal point, most of this reflected light is reflected and focused at the second focal point of the second concave mirror, and then incident on the light receiving element at the second focal point. Therefore, the diffuse light emitted from the light emitting element can be focused and irradiated to the object to be detected, and the reflected light can be focused and detected by the light receiving element, thus improving the coupling efficiency when the ratio of light incident on the light receiving element to the light emitted by the light emitting element is defined as the coupling efficiency.

In a first preferable aspect of the present disclosure, the first concave mirror and the second concave mirror are formed such that the first focal point and the second focal point are located on a common straight line across the common focal point.

According to the above configuration, since the first focal point and the second focal point are on the common straight line across the common focal point, so when the light emitting element and the light receiving element are arranged, the detection position of the object to be detected is set between the light emitting element and the light receiving element, and the object to be detected can be easily aligned with the detection position.

In a second preferable aspect of the present disclosure, the first concave mirror and the second concave mirror are formed such that a major axis of the first concave mirror passing through the first focal point and the common focal point intersects a major axis of the second concave mirror passing through the second focal point and the common focal point with a predetermined intersection angle at the common focal point.

According to the above configuration, when the light emitting element and the light receiving element are arranged, the common focal point can be located outside the case. Therefore, it is possible to set the detection position of the object to be detected at a position away from the reflective optical sensor and detect the object to be detected without contact, and also to prevent damage to the object to be detected and damage to the reflective optical sensor due to collision between the object to be detected and the reflective optical sensor.

In a third preferable aspect of the present disclosure, the light emitting element and the light receiving element are housed in the case, and the case is filled with sealing resin through which the light of the light emitting element is transmitted.

According to the above configuration, the light emitting element, the light receiving element, and the reflective surfaces of the first and second concave mirrors are protected by the sealing resin, thereby preventing damage to the reflective optical sensor due to collision with the object to be detected.

In a fourth preferable aspect of the present disclosure, the first concave mirror and the second concave mirror have a light blocking wall between them that prevents the light of the light emitting element from entering directly into the second concave mirror.

According to the above configuration, the light of the light emitting element is prevented from entering the light receiving element without being reflected by the object to be detected, thereby preventing misdetection of the object to be detected.

According to the reflective optical sensor of the present disclosure, coupling efficiency can be improved.

### BRIEF DESCRIPTION OF THE DRAWINGS

FIG. 1 is a plan view of a reflective optical sensor according to a first embodiment of the present disclosure;

FIG. 2 is a cross-sectional view taken along the line II-II in FIG. 1;

FIG. 3 is a diagram of an ellipse;

FIG. 4 is a diagram for assembling the reflective optical sensor;

FIG. 5 is an example of ray tracing simulation results for the reflective optical sensor according to the first embodiment;

FIG. 6 is a diagram showing a relationship between a distance h to an object to be detected and coupling efficiency in the reflective optical sensor according to the first embodiment;

FIG. 7 is a cross-sectional view corresponding to FIG. 2 of a reflective optical sensor according to a second embodiment of the present disclosure;

FIG. 8 is an example of ray tracing simulation results for the reflective optical sensor according to the second embodiment;

FIG. 9 is a diagram showing a relationship between a distance h to an object to be detected and coupling efficiency in the reflective optical sensor according to the second embodiment;

FIG. 10 is a diagram showing a relationship between the distance h to the object to be detected, a tilt angle of a major axis of a first and second concave mirrors, and the maximum coupling efficiency obtained for the reflective optical sensor according to the second embodiment in contour form; and

FIG. 11 is a plan view showing a modification of the reflective optical sensor according to the first embodiment.

### DESCRIPTION OF EMBODIMENTS

Hereinafter, the form for implementing this disclosure is demonstrated based on embodiments.

### First Embodiment

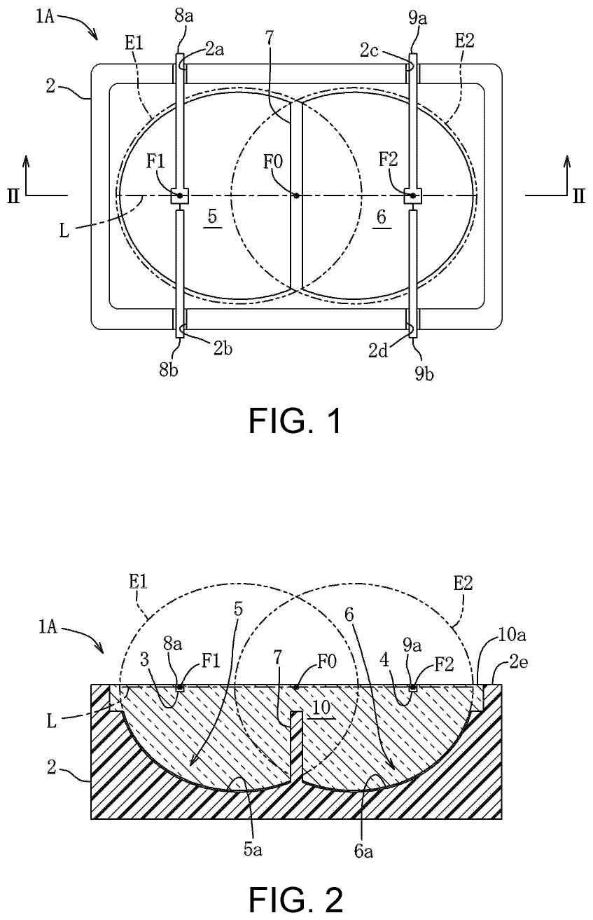

As shown in FIGS. 1 and 2, a reflective optical sensor 1A has a rectangular parallelepiped open box-shaped case 2 with an open top surface, a light emitting element 3, and a light receiving element 4. Although the open side of the case 2 will be described as the upper side of the reflective optical sensor 1A, the reflective optical sensor 1A can be used in various postures depending on the application.

At the inner bottom of the case 2, a first concave mirror 5 and a second concave mirror 6 are integrally formed in an open shape with a reflective surface facing the open side of the case 2. The first concave mirror 5 is formed with a partial concave surface of a rotational ellipse surface obtained by rotating an ellipse E1 around its major axis as a reflective surface. The second concave mirror 6 is formed with a partial concave surface of a rotational ellipse surface obtained by rotating an ellipse E2 around its major axis as a reflective surface.

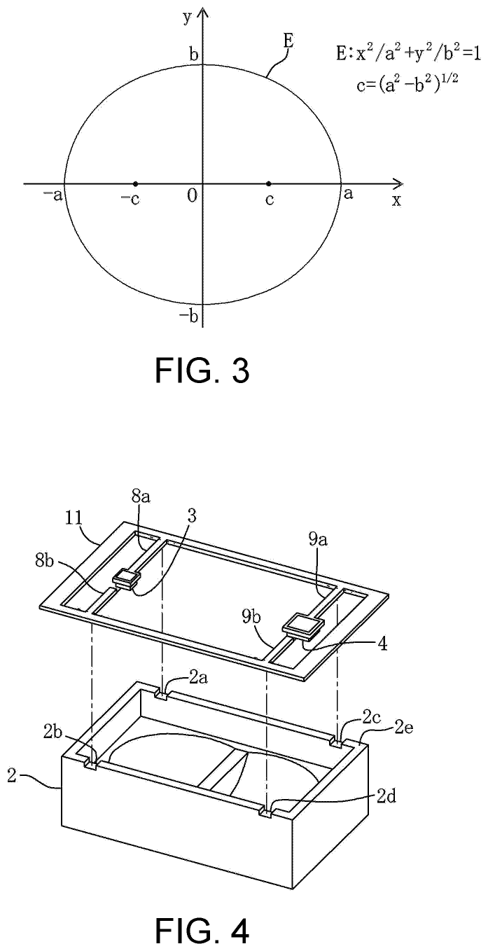

The ellipse E1 and the ellipse E2 are ellipses of the same size, for example a=4 mm and b=3.5 mm, in the ellipse E represented by x²/a²+y²/b²=1 on the x-y plane as shown in FIG. 3, but they can be of different sizes. In addition, when a>b, and c=(a²−b²)^{1/2} , the positions of (x, y)=(c, 0) and (−c, 0) are the two foci of the ellipse E.

As shown in FIGS. 1 and 2, one of the foci of the ellipse E1 forming the first concave mirror 5 is made to coincide with one of the foci of the ellipse E2 forming the second concave mirror 6 to form a common focal point F0. Then, when the other focus of the ellipse E1 is the first focal point F1 and the other focus of the ellipse E2 is the second focal point F2, the first concave mirrors 5 and the second concave mirrors 6 are arranged so that the first focal point F1 and the second focal point F2 do not overlap. At this time, the first concave mirror 5 and the second concave mirror 6 are formed such that a plane that includes the common focal point F0 and passes between the first focal point F1 and the second focal point F2 is a boundary. Here, the first concave mirror 5 and the second concave mirror 6 are arranged so that the first focal point F1 and the second focal point F2 are located on a same straight line (straight line L) across the common focal point F0, and the boundary between the first concave mirror 5 and the second concave mirror 6 is orthogonal to the straight line L.

The case 2 is formed, for example, by resin molding into the box-shape with the open top surface of a rectangular parallelepiped, and has partial concave surfaces of each rotational ellipse surface of ellipses E1 and E2 corresponding to the first and second concave mirrors 5 and 6 on the inner bottom. The first and second concave mirrors 5 and 6 are integrally formed in the case 2, with reflective films 5a and 6a containing metal such as gold and titanium formed at least these partial concave surfaces. At the boundary between the first concave mirror 5 and the second concave mirror 6, a light blocking wall 7 extending from the inner bottom of the case 2 toward the open side is formed to partition the first concave mirror 5 and the second concave mirror 6.

Recesses 2a to 2d are formed at the open end of the case 2, which are recessed from the open end face 2e of the case 2 toward the bottom for positioning a pair of first lead frames 8a, 8b and a pair of second lead frames 9a, 9b. The light emitting element 3 is fixed to one side of the tip of the first lead frame 8a, which is placed and fixed in the recess 2a. The first lead frame 8a is fixed to the recess 2a so that the light emitting surface from which the light emitting element 3 emits faces the first concave mirror 5, and the light emitting element 3 is positioned at the first focal point F1. At this case, the light emitting element 3 is housed in the case 2. The recesses 2a to 2d may be omitted and may be positioned in other ways.

The light receiving element 4 is fixed to one side of the tip of the second lead frame 9a, which is placed and fixed in the recess 2c. The second lead frame 9a is fixed to the recess 2c so that the light receiving surface of the light receiving element 4, which receive light, faces the second concave mirror 6, and the light receiving element 4 is positioned at or near the second focal point F2. At this case, the light receiving element 4 is housed in the case 2.

As shown in FIG. 2, the case 2 housing the light emitting element 3 and the light receiving element 4 is filled with sealing resin 10, and the light emitting element 3 and the light receiving element 4 are covered with the sealing resin 10. The first lead frames 8a, 8b and the second lead frames 9a, 9b may also be covered with the sealing resin 10. The sealing resin 10 is an epoxy-based synthetic resin that has a translucent property that allows the light from the light emitting element 3 to pass through, for example, visible or infrared light. The sealing resin 10 protects the light emitting element 3, the light receiving element 4, and the reflective surfaces of the first and second concave mirrors 5 and 6, and restricts the swinging of the light emitting element 3 and the light receiving element 4. If external vibrations are not transmitted to the light emitting element 3 and the light receiving element 4, the sealing resin 10 may be omitted.

A surface 10a of the sealing resin 10 is formed flat so as to match the open end surface 2e of the case 2, except for the portions of the first lead frames 8a, 8b and the second lead frames 9a, 9b. The surface 10a of the sealing resin 10 is coincident with the plane including the first focal point F1, the second focal point F2, and the common focal point F0, or is a near plane of the common focal point F0 parallel to the plane. Then, the position of the common focal point F0 or the near (upper) side of the common focal point F0 becomes a detection position of the object to be detected.

The first lead frames 8a, 8b and the second lead frames 9a, 9b are each elongated members made of, for example, kovar (an alloy containing iron, nickel, and cobalt), so it is not easy to attach them to the case 2 individually. Therefore, as shown in FIG. 4, the light emitting element 3 and light receiving element 4 are fixed and connected electrically by bonding wires, for example, to the first lead frames 8a, 8b and second lead frames 9a, 9b, which are integrally formed with the rectangular frame 11. Then, the first lead frames 8a, 8b and the second lead frames 9a, 9b are placed in the corresponding recesses 2a to 2d together with the frame 11 at the same time. After sealing with the sealing resin 10, the frame 11 is cut off and removed by cutting the base end portions of the first lead frames 8a, 8b and the second lead frames 9a, 9b, for example, as shown by dashed lines.

The frame 11 with the first lead frames 8a, 8b and the second lead frames 9a, 9b can also be formed in tape or sheet form so that the frame 11 is continuous in a plane. In this case, the light emitting element 3 and light receiving element 4 can be easily fixed and electrically connected, and can be attached continuously or simultaneously to a plurality of cases 2 arranged at predetermined intervals, for example, thus improving manufacturing efficiency.

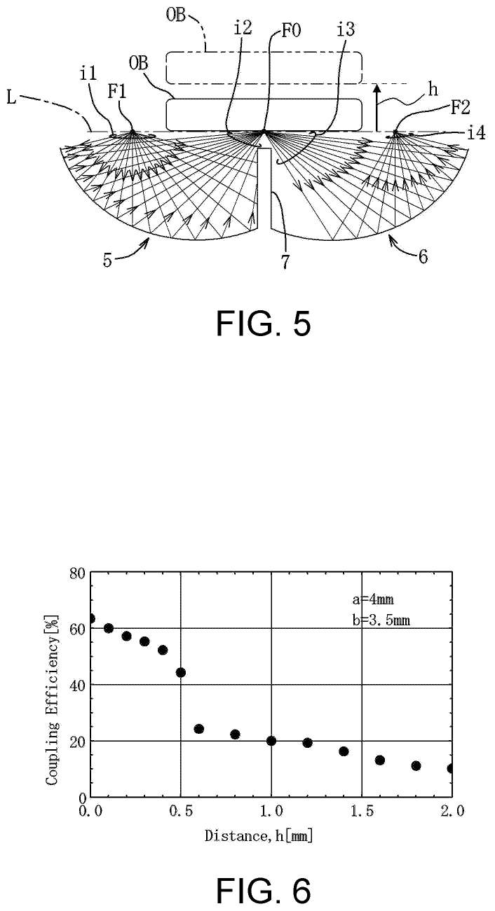

As shown in FIG. 5, due to the nature of an ellipses, a part of light i1 emitted from the light emitting element 3 at the first focal point F1 is reflected by the first concave mirror 5 and focused at the common focal point F0 such as light i2. The light blocking wall 7 prevents the light emitted from the light emitting element 3 from entering directly into the second concave mirror 6. The light emitting element 3 is a light emitting diode with an irradiation angle of 150°.

When an object OB to be detected is positioned at or near the common focal point F0, the reflected light i3 of the light i2 reflected by the object OB to be detected is reflected by the second concave mirror 6 and is focused on the second focal point F2 as reflected light i4. Then, the reflected light i4 enters the light receiving element 4 at the second focal point F2, and a photocurrent is output. On the other hand, when there is no object OB to be detected, the light i2 reflected by the first concave mirror 5 from the light emitting element 3 does not enter the second concave mirror 6 and goes out, so it does not enter the light receiving element 4. Therefore, the object OB to be detected can be detected by the light receiving element 4 detecting the reflected light i4 that is reflected the reflected light i3 by the second concave mirror 6, where the reflected light i3 is the light of the light emitting element 3 reflected by the object OB to be detected.

When coupling efficiency is defined as a ratio of light incident on light receiving element 4 to the light emitted by the light emitting element 3, the higher the coupling efficiency, the greater the photocurrent output. Therefore, it is desirable to achieve high coupling efficiency because, for example, misdetection of object OB to be detected due to stray light can be easily prevented and, for example, the light intensity of the light emitting element 3 can be lowered to achieve low power consumption. Here, based on the ray tracing simulation as shown in FIG. 5, coupling efficiency when the object OB to be detected is separated from the common focal point F0 is shown in FIG. 6, using the distance h between the common focal point F0 and the object OB to be detected as a parameter.

When the object OB to be detected is at the common focal point F0 at a distance h=0 mm, coupling efficiency exceeds 60%. Although coupling efficiency tends to decrease as the distance h is increased, coupling efficiency is about 10% even at distance h=2 mm. High coupling efficiency can be obtained even when a certain distance h is maintained to prevent damage to the reflective optical sensor 1A and the object OB to be detected due to contact between the reflective optical sensor 1A and the object OB to be detected.

### Second Embodiment

A reflective optical sensor 1B that is a partial modification of the reflective optical sensor 1A of the first embodiment will be described. The same portions as in the first embodiment are given the same reference numerals as in the first embodiment, and the explanation thereof will be omitted.

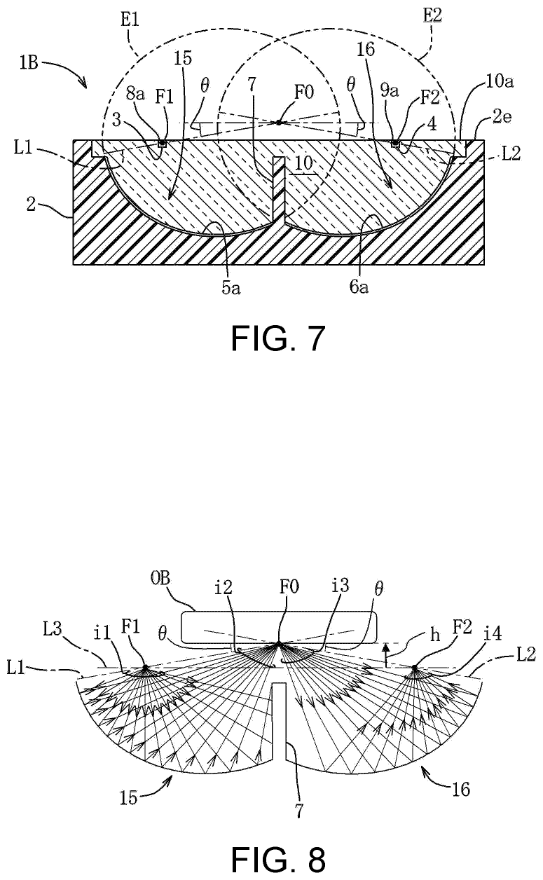

As shown in FIG. 7, the reflective optical sensor 1B has a rectangular parallelepiped box-shaped case 2 with an open top surface, a light emitting element 3, and a light receiving element 4. A first concave mirror 15 and a second concave mirror 16 are integrally formed on the inner bottom of the case 2 so that their reflective surfaces face the open side of the case 2. Similar to the reflective optical sensor 1A, one focal point of ellipse E1 forming a first concave mirror 15 is coincident with one focal point of ellipse E2 forming a second concave mirror 16 to form a common focal point F0.

Then, when the other focal point of ellipse E1 is a first focal point F1 and the other focal point of ellipse E2 is a second focal point F2, the first concave mirror 15 and the second concave mirror 16 are arranged so that the first focal point F1 and the second focal point F2 do not overlap. At this case, the first concave mirror 15 and the second concave mirror 16 are formed so that a plane containing the common focal point F0 and passing between the first and second focal points F1 and F2 is the boundary.

Here, in contrast to the reflective optical sensor 1A, in the reflective optical sensor 1B, the major axes of ellipses E1 and E2 are each inclined by an angle θ by rotating the major axes of ellipses E1 and E2 around the common focus F0. As a result, the first focal point F1 and the second focal point F2 are located below the common focal point F0. The major axis of ellipse E1 tilted by the angle θ is a straight line L1 passing through the first focal point F1 and the common focal point F0. The major axis of ellipse E2 tilted by the angle θ is a straight line L2 passing through the second focal point F2 and the common focal point F0. Since the major axes are each inclined, ellipse E1 and ellipse E2 are each in an inclined posture.

A reflective film 5a is formed on a partial concave surface of rotational ellipse surface rotated ellipse E1 around its inclined major axis (straight line L1) to form the first concave mirror 15. Similarly, a reflective film 6a is formed on a partial concave surface of rotational ellipse surface rotated ellipse E2 around its inclined major axis (straight line L2) to form the second concave mirror 16. Here, the first focal point F1, the second focal point F2, and the common focal point F0 are included in one plane (the cross section shown in FIG. 7). The angle θ of the major axis inclination is, for example, 10°, and the angle 2θ is a predetermined intersection angle of the major axes of two ellipses E1 and E2.

At the boundary between the first concave mirror 15 and the second concave mirror 16, a light blocking wall 7 extending from the bottom of the case 2 toward the open side is formed to partition the first concave mirror 15 and the second concave mirror 16.

The light emitting element 3 is fixed to one side of a tip of a first lead frame 8a, which is fixed to recess 2a among recesses 2a to 2d formed at the open end of the case 2. The first lead frame 8a is placed and fixed in the recess 2a so that the light emitting surface from which the light is emitted faces the first concave mirror 15, and the light emitting element 3 is positioned at the first focal point F1. And the light emitting element 3 is housed in the case 2.

The light receiving element 4 is fixed to one side of a tip of a second lead frame 9a which is fixed to the recess 2c. The second lead frame 9a is placed in the recess 2c so that the light receiving surface of the light receiving element 4 faces the second concave mirror 16, and the light receiving element 4 is positioned at the second focal point F2. And the light receiving element 4 is housed in the case 2. Although the figure is omitted, the light emitting element 3 is supplied with power for light emission via the corresponding pair of first lead frames 8a, 8b, and the light receiving element 4 outputs a photocurrent via the corresponding pair of second lead frames 9a, 9b.

As shown in FIG. 7, the case 2 housing the light emitting element 3 and the light receiving element 4 is filled with sealing resin 10, and the light emitting element 3 and the light receiving element 4 are covered with the sealing resin 10. The sealing resin 10 is an epoxy-based synthetic resin with a translucent property that allows light from the light emitting element 3 to pass through, for example, visible or infrared light. The first lead frames 8a, 8b and the second lead frames 9a, 9b may also be covered with the sealing resin 10.

A surface 10a of the sealing resin 10 is formed flat so as to match the open end surface 2e of the case 2, except for the portions of the first lead frames 8a, 8b and the second lead frames 9a, 9b. The surface 10a of the sealing resin 10 is coincident with the plane including the first focal point F1 and the second focal point F2, or is positioned at a near plane of the first and the second focal point F1, F2 parallel to the plane. The position of the common focal point F0 or its vicinity, which is separated from the surface 10a of the sealing resin 10, is the detecting position where the object to be detected.

As shown in FIG. 8, due to the nature of ellipses, a part of light i1 emitted from the light emitting element 3 at the first focal point F1 is reflected and focused by the first concave mirror 15 to the common focal point F0 as light i2. The light blocking wall 7 prevents the light emitted from the light emitting element 3 from entering directly into the second concave mirror 16. The light emitting element 3 is a light emitting diode with an irradiation angle of 150°.

When the object OB to be detected is positioned at or near the common focal point F0, the reflected light i3, which is the light i2 reflected by the object OB to be detected, is reflected by the second concave mirror 16 and is focused on the second focal point F2 as reflected light i4. Then, the reflected light i4 enters the light receiving element 4 at the second focal point F2, and a photocurrent is output. On the other hand, when there is no object OB to be detected, the light i2, which is reflected by the first concave mirror 15 of the light emitting element 3, does not enter the second concave mirror 16 and goes out to the outside, so it does not enter the light receiving element 4. Therefore, the object OB to be detected can be detected by the light receiving element 4 detecting the reflected light i4 that is reflected the reflected light i3 by the second concave mirror 16, where the reflected light i3 is the light of the light emitting element 3 reflected by the object OB to be detected.

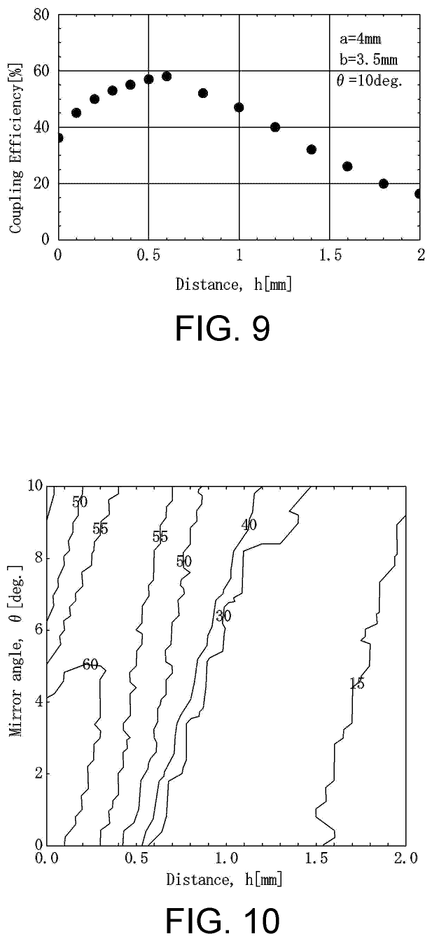

When coupling efficiency is defined as a ratio of light incident on light receiving element 4 to the light emitted by the light emitting element 3, it is desired to achieve high coupling efficiency. Here, based on the ray tracing simulation as shown in FIG. 8, the coupling efficiency when the object OB to be detected is separated from the reflective optical sensor 1B is shown in FIG. 9, using the distance h between the object OB and the plane containing the straight line L3 passing through the first and second focal points F1 and F2 as a parameter. The angle θ of inclination of the first and second concave mirrors 15 and 16 (the angle of inclination of the major axes of the ellipses E1 and E2) is 10°.

As the distance h is increased by moving the object OB to be detected away from the reflective optical sensor 1B, a coupling efficiency of 58% can be obtained when h=0.6 mm, which corresponds to the position of the common focal point F0. The coupling efficiency tends to decrease as the object OB to be detected is separated from the common focal point F0, but even at a distance h=2 mm, the coupling efficiency is about 16%. Therefore, high coupling efficiency can be obtained even when a certain distance h is secured to prevent damage to the reflective optical sensor 1B and the object OB to be detected due to contact between the reflective optical sensor 1B and the object to be detected. Since the coupling efficiency reaches its peak at a position separated from the reflective optical sensor 1B, the object OB to be detected can be detected without contact over a wide range including the distance h at which this peak occurs.

The coupling efficiency with distance h and the angle θ of inclination of the first and second concave mirrors 15, 16 (angle of inclination of the major axes of ellipses E1, E2) as parameters is shown in FIG. 10 as contour lines. The larger the angle θ, the higher the common focal point F0 is positioned upward relative to the first and second focal points F1 and F2, so the larger the angle θ, the more the range of distance h shifts toward the side where the higher coupling efficiency is obtained. Therefore, a larger angle θ is advantageous for non-contact detection of the object OB to be detected.

The functions and effects of the reflective optical sensors 1A and 1B will be explained. The reflective optical sensor 1A (1B) has the case 2 integrally formed with the first and second concave mirrors 5, 6 (15, 16), which are partially concave surfaces of the rotational ellipse surface respectively. The first and second concave mirrors 5, 6 (15, 16) are formed so that one focal point of each is the common focal point F0, and the other focal point of each (first focal point F1 and second focal point F2) does not overlap. Then, the light emitting element 3 at the first focal point F1 of the first concave mirror 5 (15) emits light i1 toward the first concave mirror 5 (15), and the light reflected by the first concave mirror 5 (15) is irradiated onto the object OB to be detected located at or near the common focal point F0. The reflected light i3 reflected by the object OB to be detected is reflected by the second concave mirror 6 (16) and enters the light receiving element 4 at the second focal point F2.

The light i1 emitted from the position of the first focal point F1 is focused on the common focal point F0 by the first concave mirror 5 (15), so that most of the light from the light emitting element 3 is irradiated onto the object OB to be detected and reflected by the detection object OB to be detected toward the second concave mirror 6 (16). Since this reflected light i3 is reflected at or near the common focal point F0, most of the reflected light i3 is reflected by the second concave mirror 6 (16) and focused on the second focal point F2 of the second concave mirror 6 (16), and enters the light receiving element 4 at the second focal point F2. Therefore, the diffused light emitted from the light emitting element 3 can be focused and irradiated to the object OB to be detected, and the reflected light can be focused and detected by the light receiving element 4, thus improving the coupling efficiency.

The first concave mirror 5 and the second concave mirror 6 of the reflective optical sensor 1A are formed so that the first focal point F1 and the second focal point F2 are located on the same straight line (on the straight line L) with the common focal point F0 therebetween. Since the first focal point F1 and the second focal point F2 are on the same straight line across the common focal point F0, when the light emitting element 3 and the light receiving element 4 are arranged, the detection position of the object OB to be detected is set between the light emitting element 3 and the light receiving element 4, and the object OB to be detected can be easily set at the detection position.

The first concave mirror 15 and the second concave mirror 16 of the reflective optical sensor 1B are formed so that the major axis (straight line L1) of the first concave mirror 15 passing through the first focal point F1 and the common focal point F0, and the major axis (straight line L2) of the second concave mirror 16 passing through the second focal point F2 and the common focal point F0, intersect at the common focal point F0 at a predetermined intersection angle. When the light emitting element 3 and the light receiving element 4 are arranged inside the case 2, the detection position of the object OB to be detected is set at a position separated from the reflective optical sensor 1B outside the case 2 to detect the object without contact. Therefore, damage to the object OB to be detected and damage to the reflective optical sensor 1B due to collision between the object OB to be detected and the reflective optical sensor 1B can be prevented.

In the reflective optical sensor 1A (1B), the light emitting element 3 and the light receiving element 4 are housed in the case 2, and the case 2 is filled with the sealing resin 10 through which light from the light emitting element 3 passes. The sealing resin 10 protects the light emitting element 3, the light receiving element 4, and the reflective surfaces of the first and second concave mirrors 5, 6 (15, 16), thus preventing damage to the reflective optical sensor 1A (1B) due to collision with the object OB to be detected.

The reflective optical sensor 1A (1B) has a light blocking wall 7 between the first concave mirror 5 (15) and the second concave mirror 6 (16) that prevents light from the light emitting element 3 from entering directly into the second concave mirror 6 (16). Since the light blocking wall 7 blocks light entering into the light receiving element 4 without being reflected by the object OB to be detected, misdetection of the object OB to be detected can be prevented.

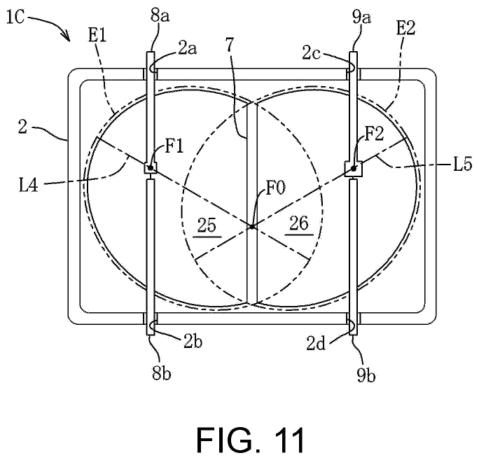

By modifying the reflective optical sensor 1A, the reflective optical sensor 1C can also be configured by forming a first and second concave mirror 25, 26 in the case 2 with the major axes of ellipses E1, E2 (lines L4, L5) intersecting at the common focus F0 on the plane containing the first focal point F1, the second focal point F2 and the common focal point F0, as shown in FIG. 11. Although the figures are omitted, instead of the first lead frames 8a, 8b and the second lead frames 9a, 9b, a lid member transparent to the light of the light emitting element 3, to which the light emitting element 3 and the light receiving element 4 are fixed and formed with plural wires electrically connected to them, may be fixed to the case 2. In the above ray tracing simulation, the refraction at the surface 10a of the sealing resin 10 is omitted. However, if the refractive index n of the sealing resin 10 relative to air is considered, the above distance h can be multiplied by 1/n. In addition, those skilled in the art can implement various modifications to the embodiments described above without departing from the purpose of the present disclosure, and the present disclosure includes such modifications.

1. A reflective optical sensor comprising a light emitting element and a light receiving element, and detecting an object to be detected by reflected light emitted from the light emitting element and reflected by the object to be detected with the light receiving element; wherein
provided is a case in a form of an open box integrally formed with a first concave mirror and a second concave mirror, each of which has a reflective surface comprising a partial concave surface of a rotational ellipse surface rotated around a major axis of an ellipse,
the first concave mirror and the second concave mirror are formed open toward an open side of the case so that one focal point of the first concave mirror is coincident with one focal point of the second concave mirror as a common focal point and a first focal point, which is the other focal point of the first concave mirror, does not overlap with a second focal point, which is the other focal point of the second concave mirror,
the light emitting element emits light from the first focal point toward the first concave mirror,
the first concave mirror reflects the light to the object to be detected which is positioned at or near the common focal point, and the second concave mirror reflects light reflected by the object to be detected, and
the light receiving element is configured to detect the light reflected by the second concave mirror at the second focal point.

2. The reflective optical sensor according to claim 1; wherein the first concave mirror and the second concave mirror are formed such that the first focal point and the second focal point are located on a common straight line across the common focal point.

3. The reflective optical sensor according to claim 1; wherein the first concave mirror and the second concave mirror are formed such that a major axis of the first concave mirror passing through the first focal point and the common focal point intersects a major axis of the second concave mirror passing through the second focal point and the common focal point with a predetermined intersection angle at the common focal point.

4. The reflective optical sensor according to claim 1; wherein the light emitting element and the light receiving element are housed in the case, and the case is filled with sealing resin through which the light of the light emitting element is transmitted.

5. The reflective optical sensor according to claim 1; wherein the first concave mirror and the second concave mirror have a light blocking wall between them that prevents the light of the light emitting element from entering directly into the second concave mirror.
